(19) United States
(12) Patent Application Publication
(10) Pub. No.: US 2009/0009232 A1
(43) Pub. Date: Jan. 8, 2009

(54) Power Switches

(76) Inventors: Jens Helfrich, Speyer (DE); Rolf Disselnkotter, Mauer (DE)

Correspondence Address: James E. Bradley, Bracewell & Patterson, L.L.P., P.O. Box 61389, Houston, TX, 77208-1389, US

(21) Appl. No.: 11/664,801

(22) PCT Filed: Aug. 24, 2005
(86) PCT No.: PCT/GB05/03309

§ 371 Date: Apr. 5, 2007

(30) Foreign Application Priority Data
Oct. 6, 2004 (GB) 0422165.1

(51) Int. Cl. H03K 17/687; H03K 17/0814

(52) U.S. Cl. 327/430

(57) ABSTRACT

A switching device suitable for operation in temperatures over 150 C comprises first 1 and second 2 transistors, the source 1S of the first transistor being connected to the drain 2D of the second transistor, the gate 2G of the second transistor being connected to the source 1S of the first transistor and the gate 1G of the first transistor being connected in use to control circuitry 3 such that current flow through the transistors is controlled in use by the application of a control signal from the control circuitry, characterised in that the first and second transistors are both operative at temperatures over 150 C.

This invention relates to a switching device suitable for operation in temperatures over 150 C.

In power electronic circuits, fast semiconductor switches are needed which can be controlled to change their state between an “off” state to block a high voltage, i.e. having high ohmic resistance and very low leakage current flow, and an “on” state to conduct a high current, i.e. having low ohmic resistance. In the case of electric field effect transistor technologies, for example junction field effect transistors (JFETs), metal oxide semiconductor field effect transistors (MOSFETs) or insulated gate bipolar transistors (IGBTs), the state of the switch can be controlled by a gate voltage, with virtually zero static current flowing into the gate connection after the switching state has changed. Because of the low complexity of the required control circuitry, these transistors are the ones predominantly used in power circuits.

At high operating temperatures the major limitation is the intrinsic leakage current of such power semiconductor switches from thermally generated charge carriers. The leakage current is an exponential function of temperature. At high temperatures and therefore high leakage currents, the power dissipation in the device at high blockage voltages becomes high, leading to further temperature increase which in turn leads to higher losses and so on. A thermal runaway will take place, which may result in the thermal destruction of the device or in a short circuit.

State of the art silicon power switches like MOSFETs or IGBTs with high blocking voltages, for example from 100V to over 1000V, are limited in their maximum safe operating temperature clearly below 200 C.

Above 200 C, only power devices with larger bandgap materials than silicon, such as GaAs, SiC, GaN and diamond can be used. However, with these materials the state of the art device technology for reliable high temperature switches with high blocking voltages is limited to normally-on transistor types such as JFETs. This has two main disadvantages; firstly that the device is always turned on, i.e. with low resistance, in a passive state without any control voltage applied, which is undesirable in most power circuits, and secondly that in order to turn the device off, a negative voltage must be applied to the gate, which requires a complex control circuit.

An alternative approach is to use switches fabricated in an enhanced silicon technology such as silicon on insulator (SOI), where the active area of the device is separated by a silicon oxide insulation layer from the bulk material. This will also lead to strongly decreased leakage currents at high temperatures as compared to “bulk” silicon devices. Normally-off power MOSFET switches made in this technology can be used up to 300 C. This arrangement has the disadvantage that only lateral device structures are possible with SOI, which leads to low maximum blocking voltages due to higher field strengths inside active areas as compared to standard power transistors which always have vertical structures. State of the art SOI power MOSFETs exhibit blocking voltages below 100V.

Other devices such as SiC MOSFETs which would normally combine a normally-off type, with a vertical structure, high blocking voltages and low leakage currents at high temperature suffer from a poor reliability of the gate oxide at high temperatures due to the very high field strengths inside the oxide and an inferior channel mobility as compared to silicon MOSFETs.

It is an aim of the present invention to provide a power switching device which overcomes the aforementioned disadvantages.

A switching device comprising first and second transistors, the source of the first transistor being connected to the drain of the second transistor, the gate of the second transistor being connected to the source of the first transistor and the gate of the first transistor being connected in use to control circuitry such that current flow through the transistors is controlled in use by the application of a control signal from the control circuitry is described in US2004/0027753.

According to the present invention there is provided a switching device suitable for operation in temperatures over 150 C comprising first and second transistors, the source of the first transistor being connected to the drain of the second transistor, the gate of the second transistor being connected to the source of the first transistor and the gate of the first transistor being connected in use to control circuitry such that current flow through the transistors is controlled by the application of a control signal from the control circuitry, characterised in that the first and second transistors are both operative at temperatures over 150 C.

Advantageously, the transistors are operative at temperatures over 200 C.

Preferably, the first transistor is normally-on in the absence of a voltage applied to its gate, for example a MOSFET.

Advantageously, the first transistor has a larger bandgap than silicon. The first transistor may be of the silicon on insulator type.

Preferably, the second transistor is normally-off in the absence of a voltage applied to its gate, for example a JFET.

The invention will now be described, by way of example, with reference to the accompanying drawing, in which:—

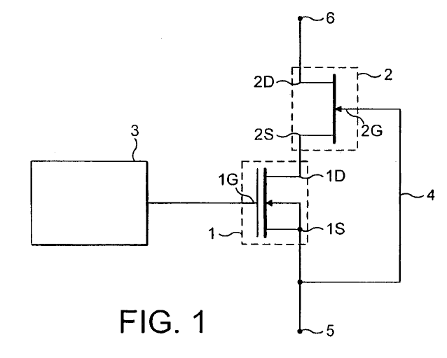

FIG. 1 shows a basic circuit diagram of a power switching circuit in accordance with the present invention.

FIG. 1 shows a switching arrangement for selectively allowing current to pass between points 5 and 6. The switching arrangement comprises two transistors 1 and 2. In order for these transistors to operate satisfactorily at high temperatures, for example in excess of 150 C, but 200 C, these transistors should have large bandgaps, i.e. larger than conventional silicon. In a preferred embodiment therefore, transistor 1 is a silicon on insulator (SOI) Power MOSFET, while transistor 2 is a silicon carbide (SiC) JFET. This arrangement allows satisfactory operation not only at temperatures over about 150 C, but also over about 200 C and in the range of up to about 300 C. With these components, transistor 1 is normally off, i.e. not allowing current to pass from source 1S to drain 1D in the absence of a voltage applied to its gate 1G. Transistor 2 is normally on, i.e. allowing current to pass from its source 2S to drain 2D in the absence of voltage applied to its gate 2G. SOI MOSFET 1 has its source 1S connected to point 5, with drain 1D connected to source 2S of SiC JFET 2. Gate 1G of the MOSFET 1 is controlled by control circuitry 3, which selectively applies control signal voltage to gate 1G. Source 1S of MOSFET 1 is also connected via path 4 to gate 2G of JFET 2. Drain 2D of JFET 2 is connected to point 6.

The switching device shown enables a normally off, reliable semiconductor switch with low leakage currents at high temperatures, e.g. over 150 C, and high voltages, e.g. over 800V, which can be used for high temperature power supplies. The normally on SiC JFET 2 acts as a blocking device for the high voltage, whereas the MOSFET 1 provides a low voltage normally off current switch. Silicon carbide has a wide bandgap and therefore inherently low intrinsic charge carrier density at high temperatures, leading to low leakage currents. Silicon on insulator technology also provides low leakage currents by separating the active area inside the device from the bulk silicon. The switching device as a whole enables a fast, normally off power switch for high temperature applications with ambient temperatures higher than 150 C, high blocking voltages, e.g. over 1000V and high switching frequencies.

Although the invention has been described with reference to the embodiment above, many other modifications and alternatives are possible within the scope of the claims.

1. A switching device suitable for operation in temperatures over 150 C comprising first and second transistors, the source of the first transistor being connected to the drain of the second transistor, the gate of the second transistor being connected to the source of the first transistor and the gate of the first transistor being connected in use to control circuitry such that current flow through the transistors is controlled by the application of a control signal from the control circuitry, characterised in that the first and second transistors are both operative at temperatures over 150 C.

2. A switching device according to claim 1, wherein the first and second transistors are operative at temperatures over 200 C.

3. A switching device according to any preceding claim, wherein the first transistor is normally-on in the absence of a voltage applied to its gate.

4. A switching device according to claim 3, wherein the first transistor is a MOSFET.

5. A switching device according to any preceding claim, wherein the first transistor has a larger bandgap than silicon.

6. A switching device according to claim 5, wherein the first transistor is of the silicon on insulator type.

7. A switching device according to any preceding claim, wherein the second transistor is normally-off in the absence of a voltage applied to its gate.

8. A switching device according to claim 7, wherein the second transistor is a JFET.

9. A switching device substantially as herein described with reference to the accompanying drawings.
